(19) United States
(12) Patent Application Publication
(10) Pub. No.: US 2009/0251129 A1
(43) Pub. Date: Oct. 8, 2009

(54) FREQUENCY MEASUREMENT DEVICE AND MEASUREMENT METHOD

(75) Inventors: Masayoshi Todorokihara, Shimosuwa-machi (JP); Takayuki Kondo, Chino-shi (JP)

Correspondence Address: OLIFF & BERRIDGE, PLC, P.O. BOX 320850, ALEXANDRIA, VA, 22320-4850, US

(73) Assignee: SEIKO EPSON CORPORATION, Tokyo (JP)

(21) Appl. No.: 12/418,000

(22) Filed: Apr. 3, 2009

(30) Foreign Application Priority Data
Apr. 7, 2008 (JP) 2008-099721

(51) Int. Cl. G01R 23/02

(52) U.S. Cl. 324/76.39; 377/19

(57) ABSTRACT

A frequency measurement device includes: a short gate time counter section that continuously measures a pulse stream signal supplied, and outputs a series of count values that behave like a pulse stream corresponding to a frequency of the pulse stream signal; and a low-pass filter that removes high frequency components from the series of count values to obtain a level signal corresponding to the frequency of the pulse stream signal supplied.

Japanese Patent Application No. 2008-099721 filed on Apr. 7, 2008, is hereby incorporated by reference in its entirety.

### BACKGROUND

1. Technical Field

The invention relates to measurement of frequency, and more particularly to measurement methods and devices capable of detecting small changes in frequency.

2. Related Art

As frequency measurement systems, a direct count system and a reciprocal system are known. According to the direct count system, pulses passing within a predetermined gate time are counted (see, for example, Patent Document: Japanese laid-open patent application JP-A-6-501554). According to the reciprocal system, a pulse period is accurately measured, and a frequency is obtained from its time reciprocal (see, for example, Non-patent document: Kazuya Katano “How to Use Time-measuring Instruments, and Introduction to Correct Use of Measurement Instruments,” Transistor Technology, Series No. 14, February 1994, p. 331). The direct count system may be realized with a relatively small-scale circuit, but a long gate time may be needed to obtain a higher frequency resolution (for example, a gate time needed for obtaining a resolution of 0.1 Hz is 10 seconds). The reciprocal system can overcome this short-coming, but its circuit for accurately measuring pulse intervals becomes larger in scale compared to that of the direct count system.

By using a QCM (Quartz Crystal Microbalance) method using a quartz oscillator, a small change in mass on a substrate surface of the oscillator can be converted to a frequency change. For example, various kinds of odor sensors can be formed by providing materials to which odor compositions adhere on the oscillator substrate surface. Odor compositions may be each composed of a unit substance or multiple substances. As sample gas is supplied to the odor sensor, its odor compositions adhere to the sensor and change the mass at the oscillator surface, whereby the frequency of the oscillator changes. A single sensor or plural kinds of sensors may be prepared to observe the change, whereby the presence of specified odor composition can be assumed. It is said that olfactory cells of about 350 different kinds are present at the human nostrils and olfactory cells of about 1000 different kinds are present in the case of the dog's nostrils. Odors are discriminated from one another by the brain's pattern recognition of ratios of odor compositions adhere to each of the olfactory cells. Learning from the olfactory sense of the living human, in order to detect and specify odor compositions, it is necessary to use many odor sensors (an array of sensors) and use a computer to analyze an output pattern from each of the sensors, to specify the pattern of the order compositions.

However, in order to detect a frequency change of each of the odor sensors, a counter and a signal processing circuit for detecting the frequency change needs to be added to each sensor output. Furthermore, although the frequency (for example, 30 MHz) of a quartz oscillator changes by adhered substance, the change is only on the order of several Hz to several hundreds Hz, and the change could be less than 1 Hz. As described above, the direct count system has a low frequency resolving power, and thus needs to take a substantially long gate time in order to improve its frequency resolving power. As errors that could occur at the time of measurement, plus/minus 1 count errors and errors caused by jitter at trigger level could occur, and in addition, errors that originate from the oscillation stability of the quartz oscillators would be superposed on the foregoing errors. The use of reciprocal system counters may supplement for the deficiencies described above, but would not be suitable for a sensor array that is equipped with many sensors, because the circuit of each of the counters becomes large.

### SUMMARY

In accordance with an advantage of some aspects of the invention, it is possible to provide a measuring method and a measuring device for measuring frequency changes with an improved frequency measurement resolving power, without using a complex circuit.

In accordance with an embodiment of the invention, a frequency measurement device is equipped with: a short gate time counter section that continuously measures a pulse stream signal supplied, and outputs a series of count values that behave like a pulse stream corresponding to a frequency of the pulse stream signal; and a low-pass filter that removes high frequency components from the series of count values to obtain a level signal corresponding to the frequency of the pulse stream signal supplied.

According to the structure described above, a pulse stream signal to be measured is sampled with a short gate time, whereby the count values corresponding to the frequency behave (are outputted) as a pulse stream. In this instance, density variations in the pulse stream corresponding to changes in the measured frequency are measured. The pulse stream is low-pass filtered whereby a frequency signal to be measured can be obtained from the pulse stream.

The gate time described above may be shorter than 1 second but longer than an operation limit of the device. For example, the gate time may be shorter than 1 second but longer than 0.01μ second.

Preferably, the gate time is shorter than one second, but longer than the operation limit of the device. For example, when gate sampling is conducted with a gate time of about 0.1 msec, for example, a performance improvement by 1 to 2 digits in terms of time resolving power, and by 2 to 3 digits in terms of SN ratio can be expected, compared to the conventional direct count system. Frequency counting and data recording may be performed with a hardware implementation, whereby measurement may be conducted with a gate time shorter than 1 μsec.

Preferably, the short gate counter section may be equipped with a counter that does not generate an insensitive period with respect to the pulse stream signal. The insensitive period here is a period in which a pulse stream signal inputted in the counter cannot be measured, which may occur at the time of resetting the counter or transferring count values. As described below, when a discontinuity occurs in an output pulse stream of the short gate time counter section due to an operation to reset the counter or the like, the data stream (values) before and after the discontinuity is cut off, which is not desirable as it functions as a sort of external disturbance.

The low-pass filter described above may be a digital filter or an analog filter.

An analog filter may be desirable. This is because a memory and a computation device that are required for a digital filter can be omitted. Also, when count values of the short gate time counter section are outputted in a pulse stream, the low-pass filter that is an analog filter functions as a D-A converter, which is convenient. When the output of the counter is n-bit data, a D-A converter may be used in a preceding stage of the low-pass filter.

The low-pass filter may preferably be a digital filter, and more preferably a moving average filter. A moving average filter can be structured in a relatively small circuit scale with a fewer amount of calculation, as compared to a general FIR filter (finite impulse response filter). Compared with IIR filters (infinite impulse response filters), moving average filters can realize linear-phase characteristics and can secure stability, and thus can enjoy the advantage of FIR filters as it is.

The low-pass filter described above may preferably have a structure in which moving average filters are serially connected in multistage (a plurality of stages). Compared to a single stage moving average filter, a multistage moving average filter has an advantage in that the performance as the low-pass filter can be improved while suppressing an increase in the computational complexity to the minimum.

Preferably, the low-pass filter may be a combination of a digital filter and an analog filter connected through a D-A converter. By this structure, the advantage of a digital filter having a good SN ratio and an analog filter that does not require processing can be combined. Compared to the processing by a digital filter alone, the combination of a digital filter and an analog filter does not require so much of the performance of the digital filter as a low-pass filter, such that the tap number of the digital filter can be substantially reduced. For example, when a single stage moving average filter is used as the digital filter, an up-down counter can be used for filter processing, whereby the circuit can be simplified in addition to the reduction in the tap number.

The counter that does not generate an insensitive period described above may preferably include a counter of a direct counting system that cumulatively counts the pulse stream signal, and a subtractor that obtains a current count value from a difference between a cumulative count value measured last time and a current cumulative count value. By this structure, a counter that does not have an insensitive period can be structured without alternately operating two counters.

### BRIEF DESCRIPTION OF THE DRAWINGS

FIG. 1 is a diagram for describing the outline of the invention.

FIG. 2 is a diagram of an example of the structure of a short gate counter section 20.

FIG. 3 a diagram of another example of the structure of a short gate counter section 20.

FIG. 4 is a graph for describing an example of count values given by the short gate counter section 20.

FIG. 5 is a graph showing an example of outputs of a low-pass filter 30.

FIG. 6 is a graph for describing a short gate time system.

FIG. 7 is a graph for describing an example of outputs by the short gate time system.

FIG. 8 is a graph for describing an example of the effect of the short gate time system.

FIG. 9 is a graph for describing the effect of an input discontinuity.

FIG. 10 is a diagram of an example of a low-pass filter (analog).

FIG. 11 is a graph for describing an example of outputs of a low-pass filter (analog).

FIG. 12 is a diagram of an example of a low-pass filter (moving average).

FIG. 13 is a figure for describing an example of moving average calculation, where each 10-segment moving average in the figure corresponds to a first stage moving average filter output value (tap number 10 in the first stage), and each 10-segment moving average corresponds to a second stage moving average filter output value (tap number 10 in the second stage).

FIG. 14 is a graph for describing an example of gain characteristics of a low-pass filter (moving average).

FIG. 15 is a graph for describing an example of a low-pass filter (moving average).

FIG. 16 is a diagram for describing an example of a low-pass filter formed from a combination of a digital filter and an analog filter.

FIG. 17 is a graph for describing an example of outputs for a digital filter (three-stage moving average filter structure) in accordance with a reference example.

FIG. 18 is a graph for describing an example of outputs of an analog filter in accordance with a reference example.

FIG. 19 is a graph for describing an output example of D/A converted outputs of a digital filter (a one-stage moving average filter structure).

FIG. 20 is a graph for describing an example of which D/A converted values are processed by an analog filter.

FIG. 21 is a diagram for describing an example in which the invention is applied to a sensor array.

FIG. 22 is a graph showing output examples of a sensor array according to a method in related art.

FIG. 23 is a graph showing output examples of a sensor array according to a method of an embodiment of the invention.

### DESCRIPTION OF EXEMPLARY EMBODIMENTS

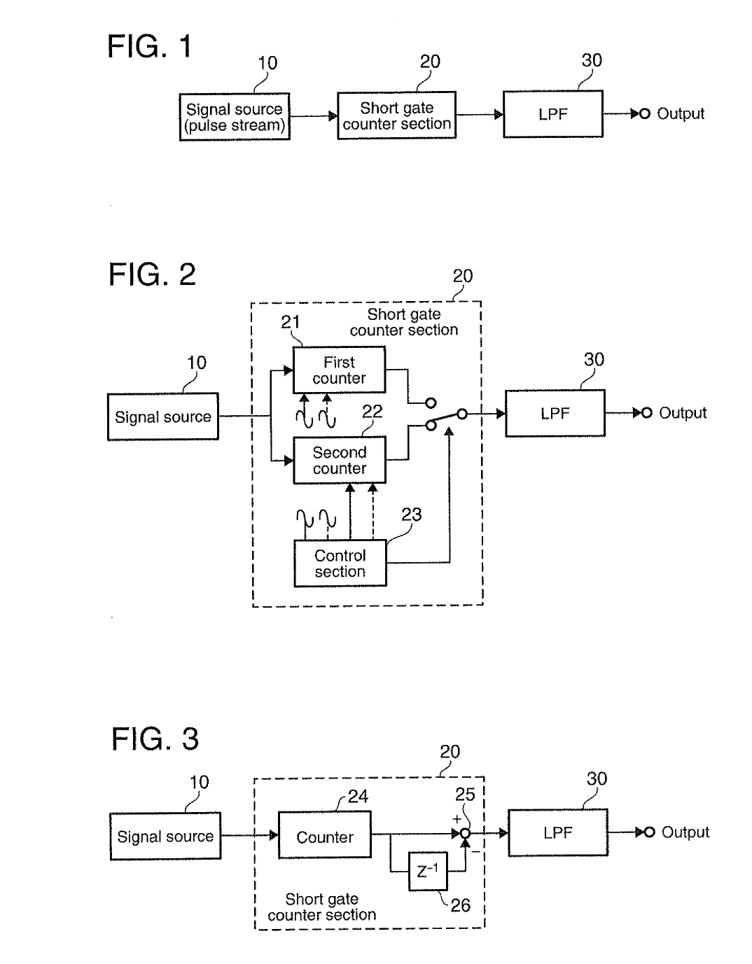

Preferred embodiments of the invention are described below with reference to the accompanying drawings. FIGS. 1-3 are schematic diagrams of frequency measurement devices in accordance with embodiments of the invention. Corresponding sections in the figures are appended with the same reference numbers.

In FIG. 1, a signal source 10 generates a pulse stream signal. The signal source 10 may be, for example, a quartz oscillator with an oscillation frequency f0 at 30 MHz, and corresponds to a detector section of an odor sensor, a gas sensor, a biosensor and the like. When odor substance adheres to the quartz oscillator, its oscillation frequency lowers according to the amount of adhered substance. The pulse stream signal is supplied to a short gate time counter section (hereafter also simply referred to as a “short gate counter”) 20. The short gate counter 20 continuously counts pulses of the supplied pulse stream signal at short gate time intervals. The count values are in a corresponding relation with the frequency (time intervals) of the pulse stream signal, and are successively supplied to a low-pass filter (LPF) 30.

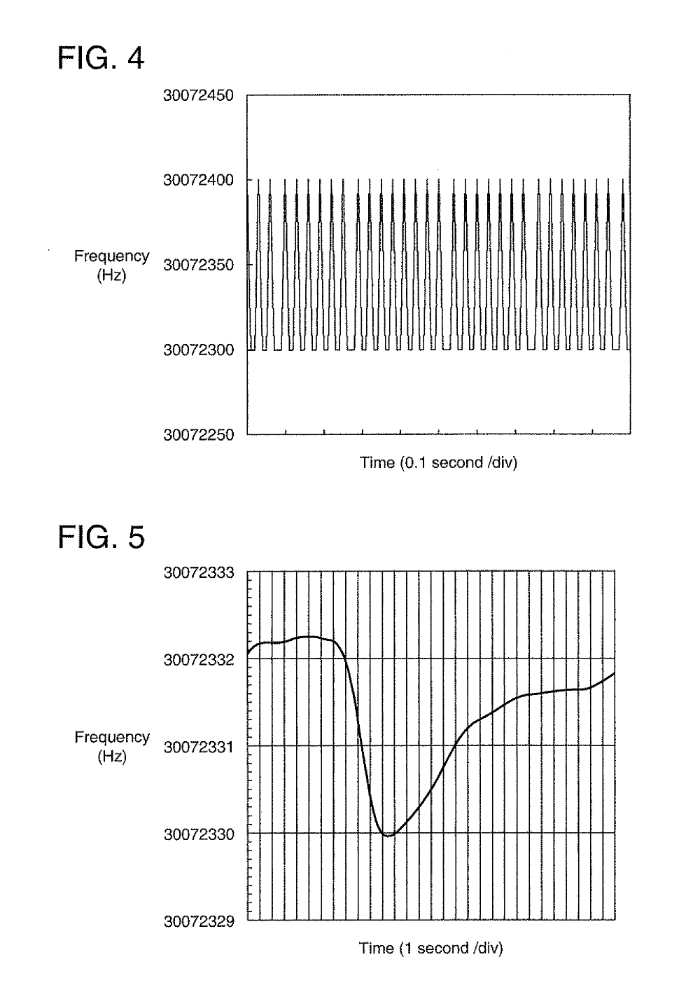

FIG. 4 shows an example of the count values. In this example, the pulse stream signal is counted at a sampling frequency of 100 Hz (at a gate time of 0.01 seconds). When the sampling frequency is 100 Hz, the frequency resolving power also lowers to 100 Hz. Therefore, information lower than 100 Hz of the supplied pulse stream signal cannot be detected by one counted value alone, but 100 counted values can be obtained in one second. The frequency that is 100 times the counted value is distributed in pulses along the time axis between 30,072,300 Hz and 30,072,400 Hz.

Here, the quantization error (±1 count error) in sampling is described. For example, the case where a pulse stream signal that is stable at 123.34 Hz is measured by a counter of the direct count system is examined.

When the gate time is 10 seconds: there are 1233 counts or 1234 counts at each 10 seconds.

By multiplying these count values by 1/10, 123.3 Hz or 123.4 Hz is displayed (at each 10 seconds). (The measurement error is 0.1 Hz.)

When the gate time is 1 second: there are 123 counts or 124 counts at each one second.

123 Hz or 124 Hz is displayed (at each one second). (The measurement error is 1 Hz.)

When the gate time is 0.1 second: there are 12 counts or 13 counts at each 0.1 second.

By multiplying these count values by 10, 120 Hz or 130 Hz is displayed (at each 0.1 second). (The measurement error is 10 Hz).

When the gate time is 0.01 second: There is one count or two counts at each 0.01 second.

By multiplying these count values by 100, 100 Hz or 200 Hz is displayed (at each 0.01 second). (The measurement error is 100 Hz).

When a pulse stream signal that is stable at one spot frequency is counted, the counted values are distributed in a pulse stream having an amplitude between two values that are determined by the gate time. On the other hand, even when the frequency of a pulse stream signal to be counted changes, if the changes are within the range of the measurement error, the counted values are likewise distributed in a pulse stream with an amplitude between two values. For example, in the case of the gate time being 0.01 second, if changes in the frequency of a pulse stream signal to be counted are contained between 100 Hz and 200 Hz, a measurement value of 100 Hz or 200 Hz can be also obtained.

As shown in FIG. 4, in the system in which sampling is conducted at a short gate time that is less than one second, count values behave like a pulse stream, and frequency (coarseness and fineness) of the pulse stream changes according to changes in the frequency that is measured. The magnitude of the oscillation frequency corresponds to the level of density of the pulse stream. Information about the frequency of a pulse stream signal counted exists in low-band components of the frequency spectrum of the count values that behave as a pulse stream. Accordingly, the low-band components are extracted (harmonic components originating from quantization errors are removed) from the count values by a low-pass filter, whereby the information about the frequency of the pulse stream signal counted can be decoded.

FIG. 5 shows an example in which high frequency components are removed by feeding the above-described stream of count values shown in FIG. 4 to a (digital) low-pass filter with the tap number being 512. As shown in the figure, the changes in the frequency of the pulse stream signal supplied are outputted as a continuous (analog) curve. Frequency changes in a region that cannot be measured by counting with a sampling period at 100 Hz, in particular, frequency changes less than 1 Hz, can be detected.

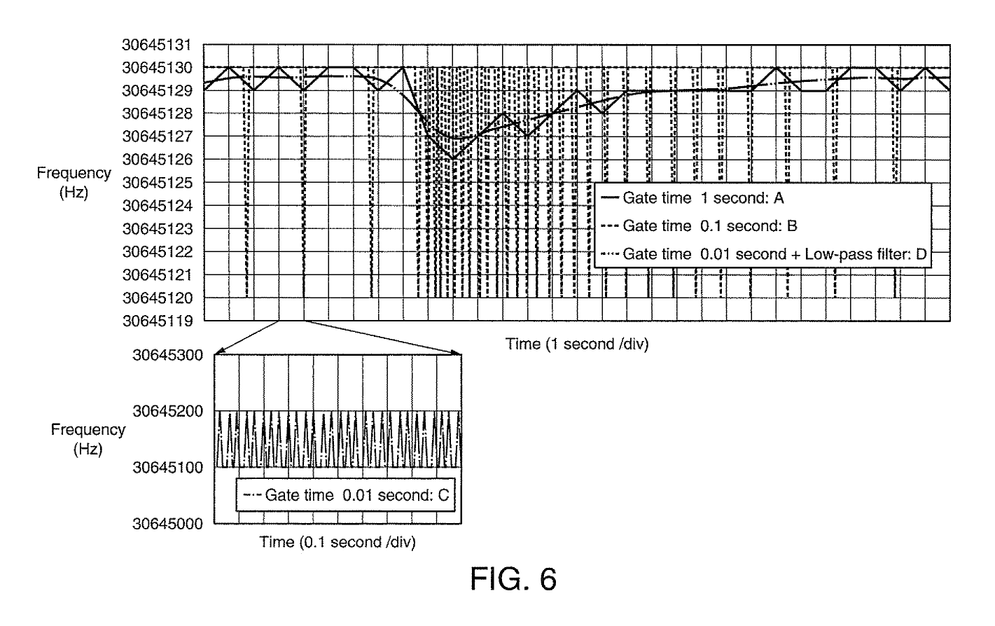

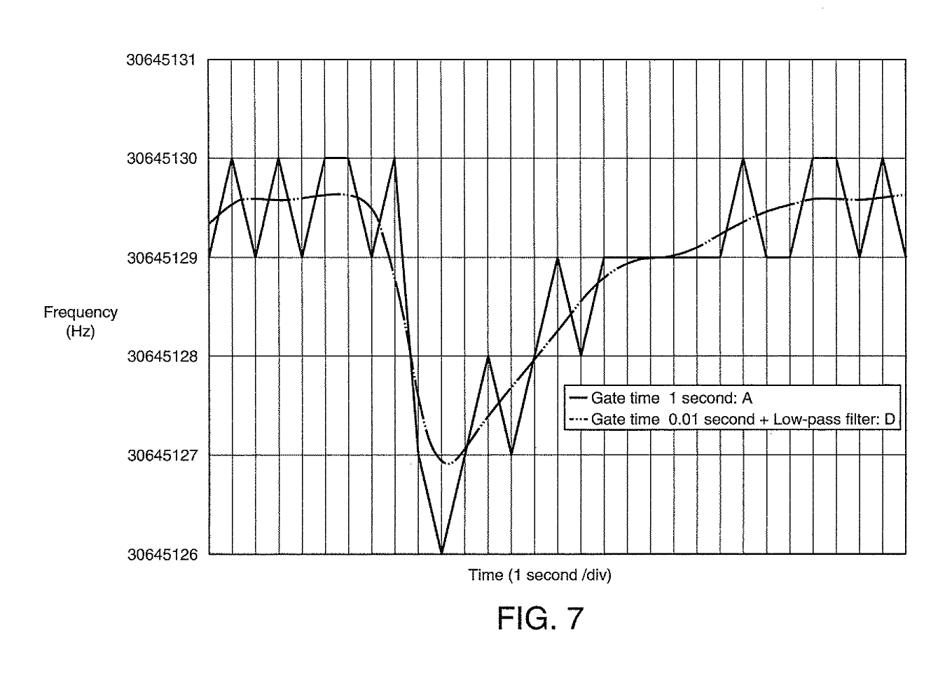

Next, the short gate time count system and the direct count system are compared, referring to FIG. 6 and FIG. 7.

In the graph shown in FIG. 6, the frequency is presented along the axis of ordinates and the time is presented along the axis of abscissas. Curve A in the figure indicates the case where sampling is conducted by a direct count system with the gate time set at one second. Curve B indicates the case where sampling is conducted by a direct count system with the gate time set at 0.1 second. Curve C indicates the case where sampling is conducted by a direct count system with the gate time set at 0.01 second. It is noted that the curve C has the time axis in a different unit (digit) and its waveform cannot be presented in the same graph, and is therefore shown below in a separate graph. Curve D indicates the case where sampling is conducted by a direct count system with the gate time set at 0.01 second plus a low-pass filter (i.e., a short gate time count system). In FIG. 7, the curve A and the curve D are compared by magnifying the range of the frequency axis in FIG. 6. The curve D in accordance with the present embodiment allows reading on the order of several 10 mHz.

It is understood from FIG. 6 that, when the gate time is less than one second, changes in the frequency of the pulse stream signal counted are contained within the measurement error, and thus the count values are either of the two values and appear in a pulse stream form. It is understood that the pulse frequency (pulse density) changes according to the magnitude of changes of the frequency. In other words, it is understood that the count values that behave like a pulse stream include information about the frequency of the pulse stream signal counted along the time axis direction. Therefore, although the measurement error contained in each measurement value may expand as a result of shortening the gate time, this is believed not to have any impact. When the gate time is one second, the curve appears zigzag and frequencies below 1 Hz are not recognizable. However, by conducting a process to remove high frequency components from the curve by a low-pass filter, smooth characteristics similar to the characteristics of the present embodiment can be similarly obtained. Accordingly, even when the gate time is 1 Hz, the system of the present embodiment is applicable when frequency changes are in a bandwidth lower than 1 Hz and slow.

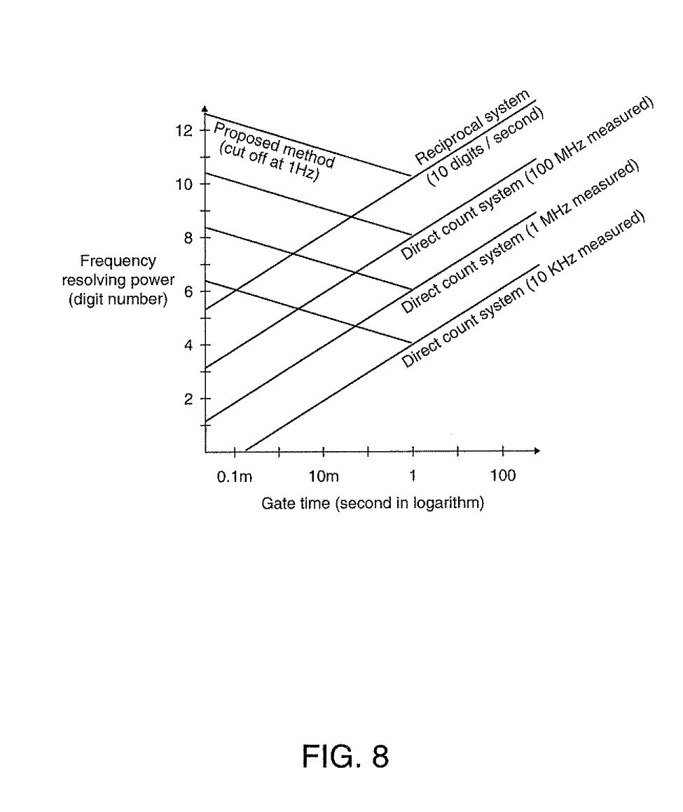

In this manner, according to the short gate time count system, by shortening the gate time (making the sampling frequency higher), a stream of many measurement values can be obtained even though each measurement error becomes greater, high frequency components can be removed by a low-pass filter, and therefore the frequency measurement resolving power is improved, as shown in FIG. 8. As the circuit scale can be suppressed to a small scale, multichannel implementation can be readily made. With an analog low-pass filter, the present embodiment is also applicable to analog outputs.

FIG. 2 shows a first example of the structure of the short gate counter section 20 described above. It is desired that the short gate counter section 20 measures a pulse stream signal supplied from the signal source without interruption (without having an insensitive period for the inputted signal).

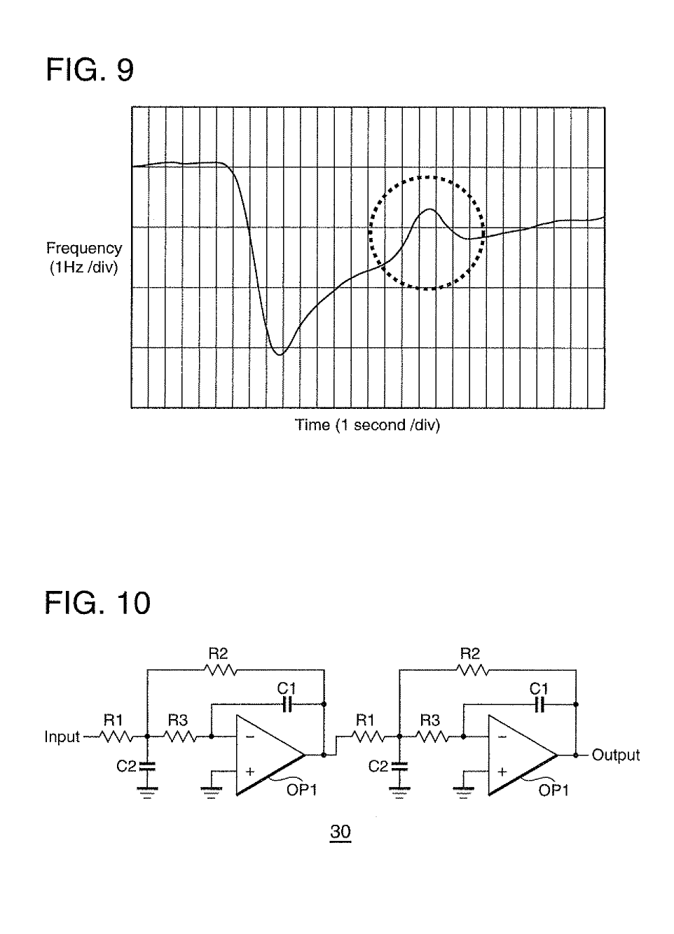

FIG. 9 shows an example of frequency outputs of a low-pass filter when its counting is interrupted (i.e., when the stream of count values to the low-pass filter is interrupted). It is understood that such interruption appears as an external disturbance as indicated in a dotted circle in the figure.

Accordingly, the first embodiment example is provided with two counters, a first counter 21 and a second counter 22. A pulse stream signal is supplied to both of the first counter 21 and the second counter 22. A control section 23 transmits a gate signal and a reset signal to each of the counters such that outputs from the both counters are supplied to a low-pass filter 30 through a switch. Measured values are alternately outputted from the two counters, such that, while one of the counters is counting, the other counter performs resetting or transferring data, thereby avoiding an insensitive period that may be generated during resetting of the counter and transferring data. It is noted that the control section 23 may be implemented as hardware, but may also be implemented by software using a personal computer or the like.

FIG. 3 shows a second example of the structure of the short gate counter section 20. This embodiment example uses a single counter 24. The counter 24 is a counter of a direct count system, and always counts sampled pulse signals and output their cumulative value (does not reset the values). The output of the counter 24 is sent to a subtractor 25 and a register 26 that retains a previous cumulative value. The subtractor 25 subtracts the previous cumulative value from a latest cumulative value outputted from the counter 24 to obtain a latest count value, and supplies the same to the low-pass filter 30. Overall operations of the device are generally the same of those of the measurement device shown in FIG. 1.

FIG. 10 shows an example in which the low-pass filter 30 is formed from an analog circuit. In this example, low-pass filters, each composed of resistors R1-R3, capacitors C1 and C2 and an operation amplifier OP1, are connected in two stages. When the short gate counter 20 outputs data in one-bit serial, the data can be inputted in the low-pass filter 30 as is. When the short gate counter 20 outputs data in n-bit, the data can be inputted through a D-A converter.

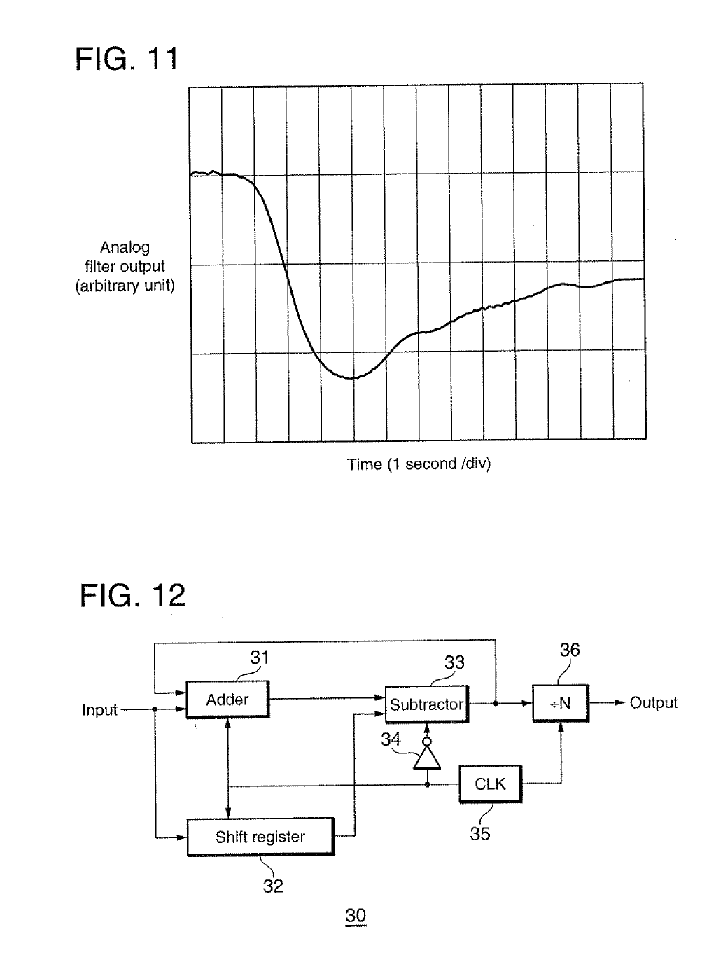

FIG. 11 shows an example of outputs of an analog low-pass filter 30 when the sampling frequency is 1000 Hz.

FIG. 12 shows an example of the structure of the low-pass filter 30 that is formed from a moving average filter. The low-pass filter 30 in the figure has an adder 31, a shift register 32, a subtractor 33, an inverter 34, a control section 35 that supplies operation timing clocks to each of the sections, and a divider 36.

Counted values outputted from the counter are given to both of the adder 31 and the shift register 32 that is equipped with storage regions corresponding to the tap number. N number of data that are subject to average value calculation sequentially move in synchronism with other data within the shift register 32. The total value obtained in a previous calculation is supplied to the other input of the adder 31, and the adder 31 adds the latest count value with the previous total value. The counted value in the leading (old) data in the shift register 32 is removed from the cumulative added value by the subtractor 33, and the result is set as a latest total value. The latest total value is returned as a previous total value to the adder 31, and the latest total value is also divided by the number of subject data N by the divider 36. The calculation described above is performed for the entire data, whereby moving average values can be obtained. It is noted that the divider has a function of scaling the output values to a frequency (Hz), but such function may be omitted if the scaling is not of concern. Also, the moving average filter is formed in multiple stages, the divider may be provided only at the last stage.

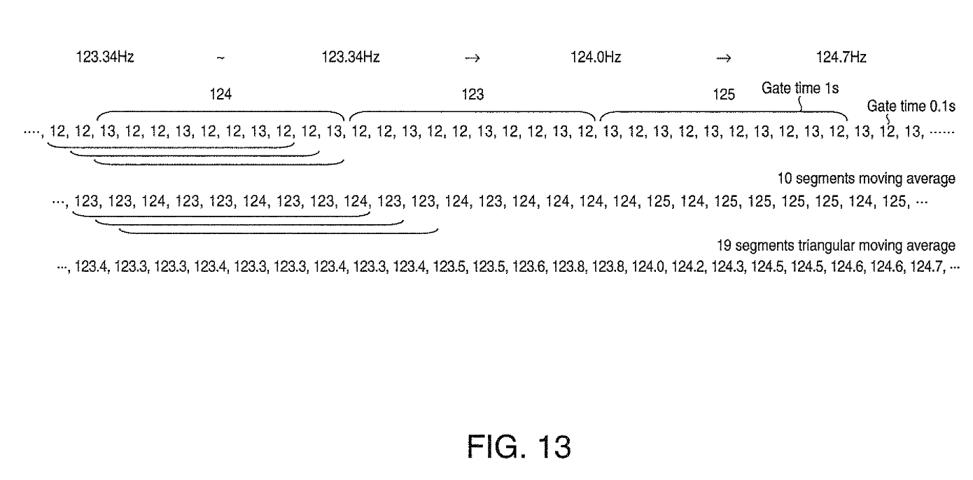

FIG. 13 is a chart schematically describing outputs of the moving average filter. In this example, it is assumed that the frequency of a pulse stream signal subject to measurement gradually changes from its state being maintained at 123.34 Hz to 124.7 Hz. When sampling at the gate time at 0.1 second, counted values of either 12 or 13 are sent in a certain ratio from the counter 20. Three sets of the total of 10 data are 124, 123, 125 . . . and the values move toward 124.7 Hz. Here, ten counted values (tap number 10) of 12 or 13 are subject to moving average calculation (moving average in the first stage). It is understood from the moving average values in the first stage that the appearance of data with greater values increases as the values move to the right. Furthermore, this tendency becomes stronger when moving average values in the second stage (tap number 10) are calculated, using the moving average values in the first stage as inputs, and the accuracy also improves. Using the moving average filters in multiple stages corresponds to steepening the attenuation slope that is the characteristic of the low-pass filter, and at the same time corresponds to removing high frequency components from the frequency spectrum of the pulse stream composed of 12 and 13.

In accordance with the embodiment example, moving average filters (low-pass filters) are connected in three stages (a three-stage moving average filter with the total tap number being 4096: tap numbers being 818 (first stage); 1640 (second stage); and 1640 (third stage)).

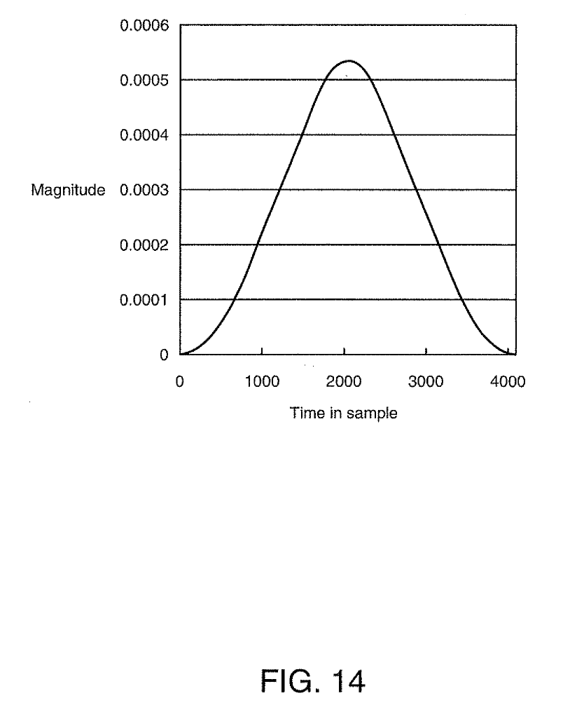

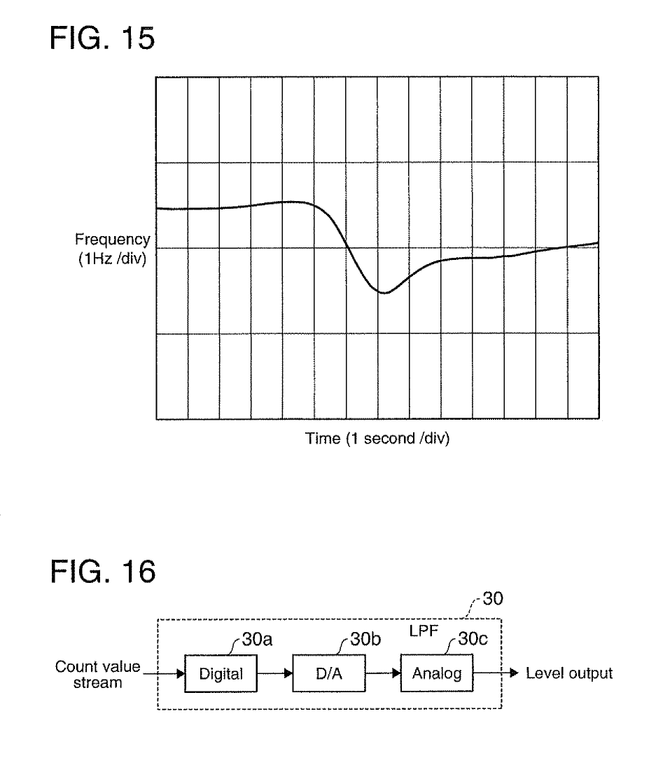

FIG. 14 shows impulse responses of the three-stage moving average filter. FIG. 15 shows an example of outputs of the three-stage moving average filter. In this manner, frequency changes less than 1 Hz can be measured.

Next, a low-pass filter 30 that is formed by a combination of a digital filter and an analog filter is described with reference to FIGS. 16 to 20.

FIG. 16 shows an example of a low-pass filter 30 that is formed from a digital filter (low-pass filter) 30a, a D/A converter 30b and an analog filter (low-pass filter) 30c. This structure has the following advantages.

First, when the sampling frequency is high, and a signal change in a frequency measured is small with respect to the sampling frequency, the SN ratio may lower in the analog filter processing, even when the digital filter processing can perform demodulation without any problem. This is because the change in the output after filter processing which corresponds to the signal change in the frequency measured is small as compared to the amplitude of the pulse, which causes the apparent dynamic range to reduce. In the case of the digital filter processing, information of the quantized count value does not deteriorate, and thus the aforementioned problem does not occur

For example, when a frequency change of 100 Hz is to be observed by using a sampling frequency of 1000 Hz, a voltage change of 100 mV would be observed when a pulse of 1000 mV is processed with an analog filter. In the same condition, when a frequency change of 0.1 Hz is to be observed, a voltage change would be 0.1 mV. Therefore, for example, in the environment where noise of 1 mV is present in measurement, a signal of 0.1 Hz cannot be detected.

On the other hand, information of a frequency that is quantized as a count value would not deteriorate through digital processing, and the aforementioned problem would not occur in the digital filter processing. Accordingly, by combining with a digital filter, the SN ratio would be improved. More concretely, as described above, an output of the digital filter 30a is D-A converted by the DA converter 30b, and inputted in the analog filter 30c.

Compared to processing by a digital filter alone, the combination of the digital filter 30a and the analog filter 30c does not require so much of the performance of the digital filter 30a as a low-pass filter, such that the tap number can be substantially reduced. In particular, when a single stage moving average filter is used as the digital filter 30a, an up-down counter can be used for filter processing, whereby the circuit can be simplified in addition to the reduction in the tap number.

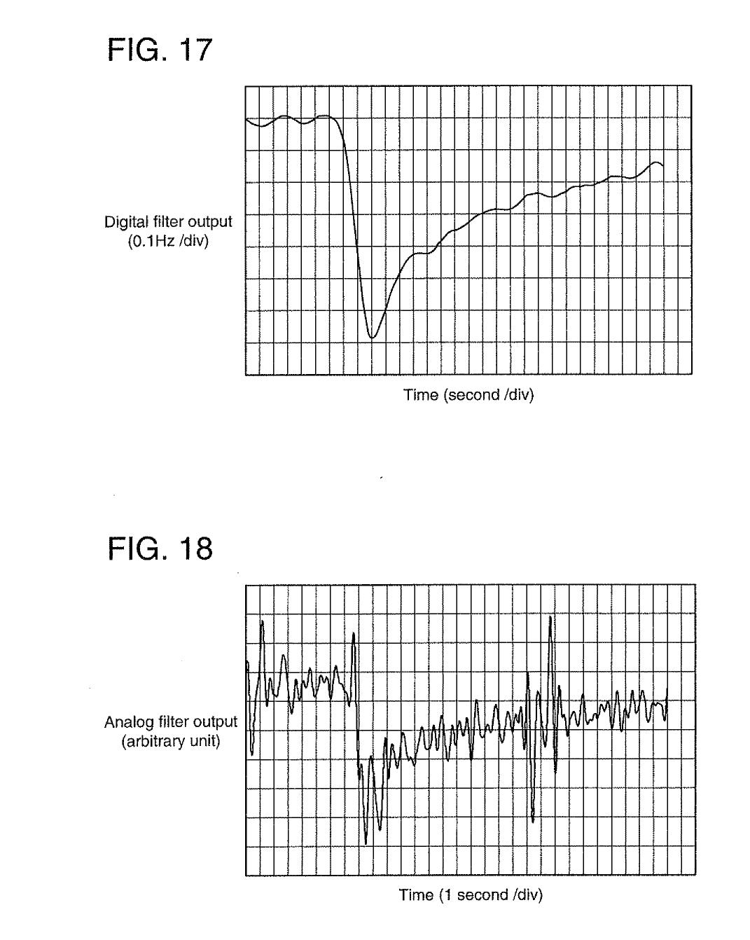

Referring to FIGS. 17 to 20, an example of characteristics of the low-pass filter 30 that is structured with a digital filter and analog filter combination, when counted with a sampling frequency of 1000 Hz, shall be described.

First, FIG. 17 shows, as a comparison example, an example of outputs of the low-pass filter 30 by digital filter processing alone (a three-stage moving average filter with the tap number being 4096). Also, FIG. 18 shows, as a comparison example, an example of outputs of the low-pass filter 30 by analog filter processing alone. It is observed that noise has a large impact (lowers the SN ratio) in the case of the analog filter.

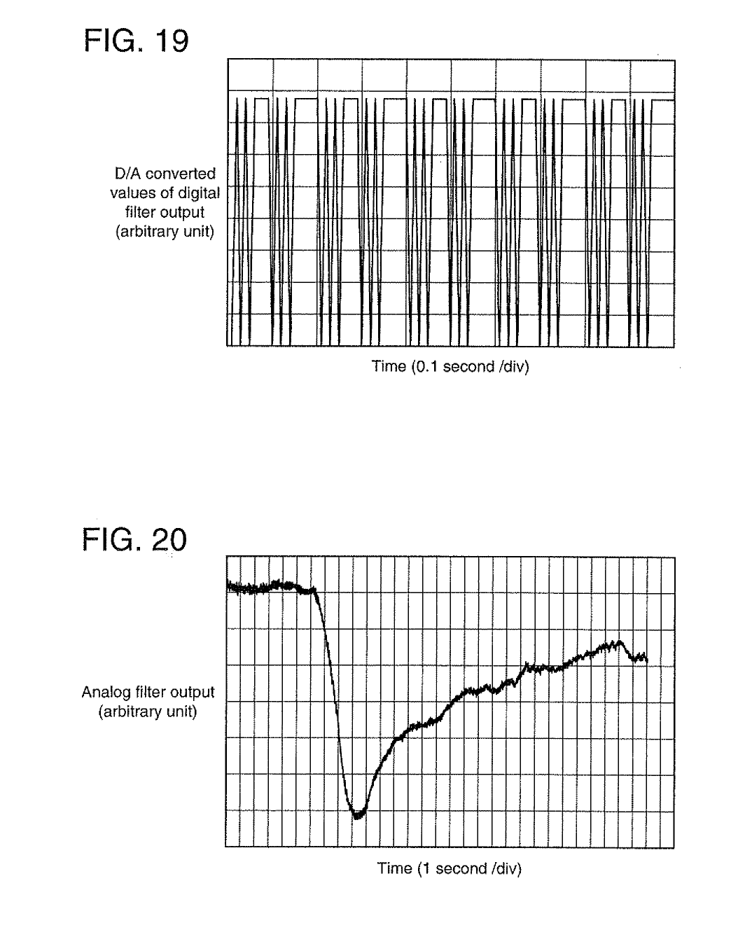

As shown in FIG. 16, the low-pass filter 30 is formed from a digital filter 30a (a single stage moving average filter with the tap number being 128), a D/A converter 30b and an analog filter 30c, and FIG. 19 shows an output example of DA converted values of outputs of the digital filter 30a. The tap number of the digital filter 30a (a single stage moving average filter with the tap number being 128) is substantially reduced as compared to the comparison example (a three-stage moving average filter with the tap number being 4096).

FIG. 20 shows an example in which the outputs of the D/A converter shown in FIG. 19 are analog-processed by the low-pass filter 30c. It is noted that an example of the structure of the analog low-pass filter is shown in FIG. 10. As shown in FIG. 20, compared to the case of the analog low-pass filter alone shown in FIG. 18, the SN ratio is improved, and signals can be detected in a manner similar to the case shown in FIG. 17 where the digital filter alone is used. As described above, the tap number of the digital filter 30a is considerably reduced.

In this manner, by forming a low-pass filter with a digital filter and an analog filter, a reduction in the SN ratio can be prevented, the tap number of the digital filter can be reduced (the amount of computation can be reduced), and the circuit can be simplified.

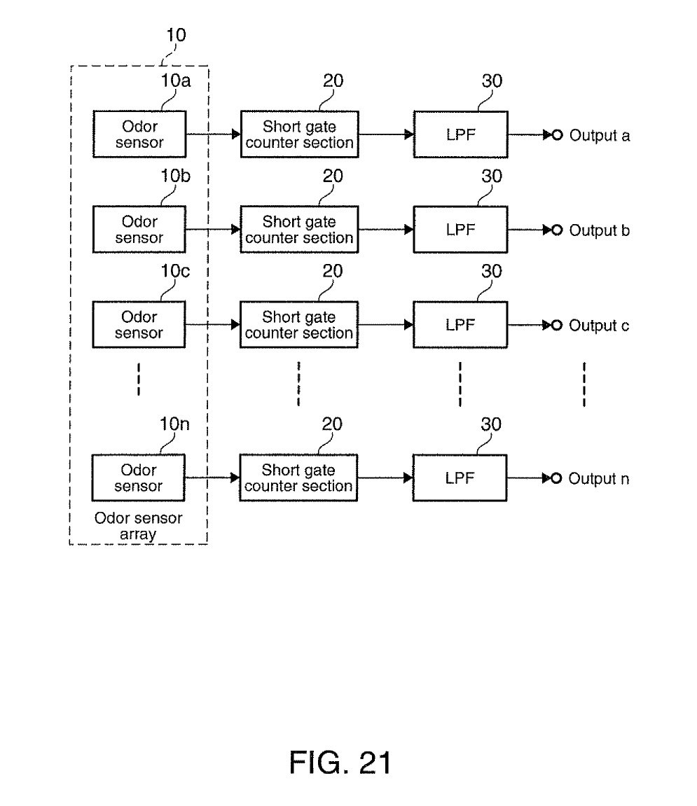

FIG. 21 shows an example in which frequency measurement devices in accordance with the present embodiment are provided on an odor sensor array as a signal source 10 equipped with many odor sensors 10a-10n. Short gate sensor sections 20 and low-pass filters 30 are the same as those described above, and therefore their description shall be omitted.

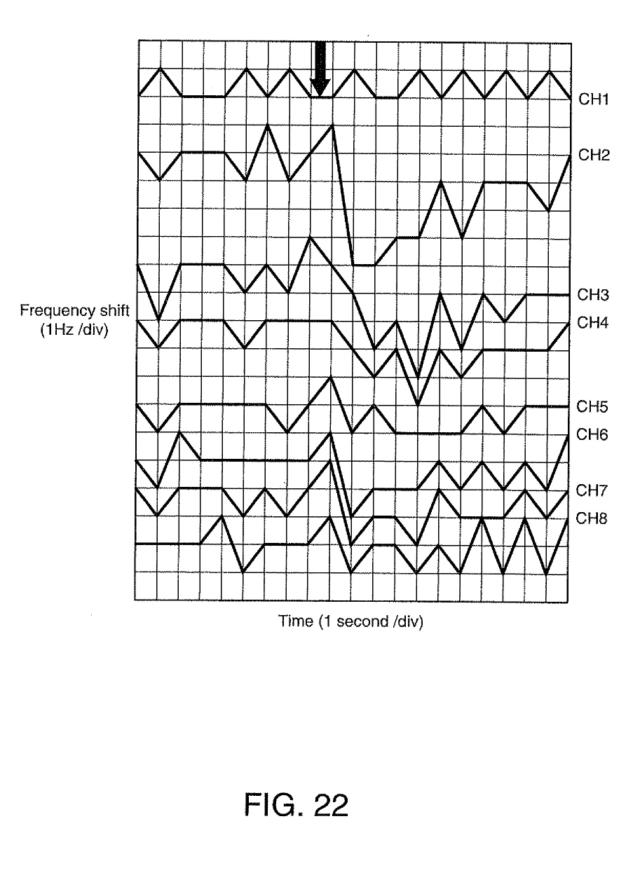

FIG. 22 shows an example of outputs of eight channels of the sensor array when measured with a sampling frequency at 1 Hz by a direct count system of related art. During the measurement, an odor substance was supplied for several seconds at a point indicated by an arrow. As the odor substance adheres to the sensor, its frequency was reduced, and then the adhered odor substance was separated in about 10 seconds.

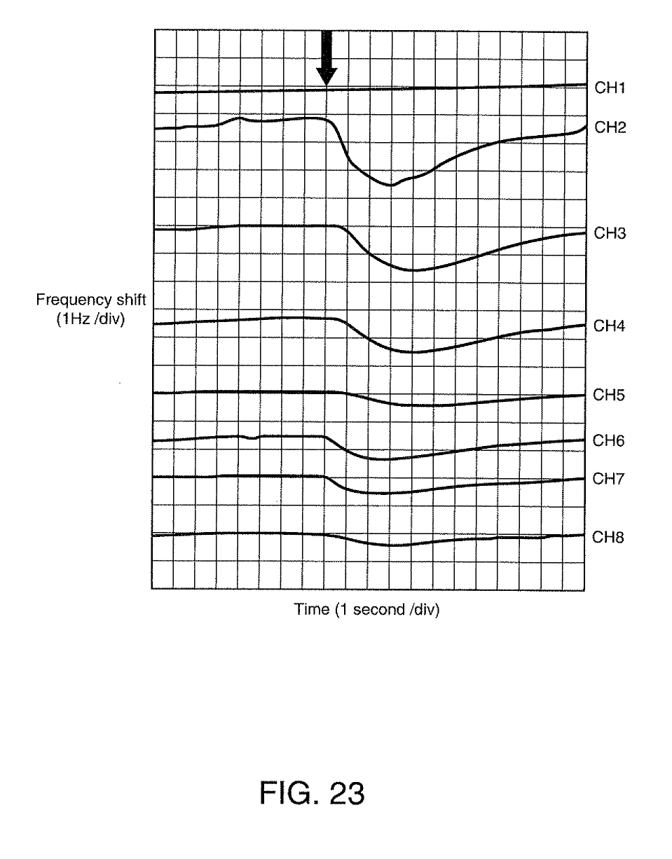

FIG. 23 shows an example in which measurement was conducted in the same condition as described above by a short gate time count system in accordance with the embodiment of the invention. It is observed that the time resolving power and the frequency resolving power are both improved. The short gate time count system does not make its circuit complicated, and therefore can be favorably used for a multi-sensor module (or in a substrate) and the like.

As described above, by using the system in which a short gate time is used for counting and counted values are passed through a low-pass filter, the circuit does not become complex, as compared to the reciprocal system. The time and frequency resolving powers can be concurrently improved. The system in accordance with the present embodiment is suitable in cases where a signal is measured in a condition where a specified sampling frequency causes oversampling with respect to the signal to be measured. Also, because the direct count system in related art would likely be influenced by duty cycle modulation, some devises may be needed when this influence cannot be ignored. According to the system of the present embodiment, the influence would be reduced by using a high sampling frequency such that any particular device would not be required.

Also, a short gate time count system is a system in which the gate time is shortened to increase measurement points, and high frequency spectrum components in the data stream are removed, thereby obtaining count values, which considerably improves the frequency resolving power. However, because each one of the measured values has a large measurement error, one missing measurement point would have a relatively large impact on the resolving power. Accordingly, by using a counter that is capable of counting pulse signals without interruption, the measurement error can be reduced.

It is effective to use a counter that does not require resetting, such as the one proposed in the embodiment example. To provide a structure without having an insensitive period that may be generated at the time of a resetting operation, a data reading operation and the like, a system using two counters that are alternately switched may be used. However, such a system results in a greater circuit scale. The system described above may be substituted by a system using two latch circuits that are alternately switched. In this case, a count value can be calculated by subtracting a previous measurement value from a current measurement value. When the counter has an operation frequency lower than the sampling frequency, the calculation time can have some margin. When the measurement value is smaller than the previous measurement value, which corresponds to an instance when the counter's digit goes up to the next digit, a correction is made by adding the maximum count value of the counter to the measurement value. As a result, the system requires only one counter, whereby the circuit scale would not become larger.

By using a device equipped with the system in accordance with the embodiment of the invention, the signal processing of the present embodiment can be applied to measurement values that are obtained from a common frequency counter without regard to the type of the count system, whereby the resolving power of the sensor is improved without adding changes to the measurement system. Counters that are designed in consideration of the system of the present embodiment have a smaller circuit scale, compared to that of counters having the same performance in accordance with the conventional system, and can be readily implemented in a multichannel system. The counters of the present embodiment may be favorably used for odor sensors, gas sensors, biosensors, A-D converter elements using frequency changes, and the like.

What is claimed is:

1. A frequency measurement device comprising:
a short gate time counter section that continuously measures a pulse stream signal supplied, and outputs a series of count values that behave like a pulse stream corresponding to a frequency of the pulse stream signal; and
a low-pass filter that removes high frequency components from the series of count values to obtain a level signal corresponding to the frequency of the pulse stream signal supplied.

2. A frequency measurement device according to claim 1, wherein the gate time is shorter than 1 second but longer than an operation limit of the device.

3. A frequency measurement device according to claim 1, wherein the short gate counter section is equipped with a counter that does not generate an insensitive period with respect to the pulse stream signal.

4. A frequency measurement device according to claim 1, wherein the low-pass filter is one of a digital filter and an analog filter.

5. A frequency measurement device according to claim 1, wherein the low-pass filter is a combination of a digital filter and an analog filter.

6. A frequency measurement device according to claim 1, wherein the low-pass filter is a multistage moving average filter.

7. A frequency measurement device according to claim 3, wherein the counter that does not generate an insensitive period includes a counter of a direct counting system that cumulatively counts the pulse stream signal, and a subtractor that obtains a current count value from a difference between a cumulative count value measured last time and a current cumulative count value.

8. A frequency measurement method comprising the steps of:
continuously measuring a pulse stream signal supplied with a short gate time and forming a series of count values corresponding to a frequency of the pulse stream signal; and
removing high frequency components from the count values to obtain a level signal corresponding to the frequency of the pulse stream signal.

9. A frequency measurement method according to claim 8, wherein the gate time is shorter than 1 second but longer than 0.01 μsec.

10. An apparatus comprising the frequency measurement device recited in claim 1.

11. A frequency measurement device comprising:
a short gate time counter section that continuously measures a pulse stream signal, and that outputs a series of count values; and
a low pass filter that removes high frequency components of the series of count values to obtain a level signal.
